(19) United States
(12) Patent Application Publication
(10) Pub. No.: US 2015/0138475 A1
(43) Pub. Date: May 21, 2015

(54) ARRAY SUBSTRATE AND LIQUID CRYSTAL DISPLAY PANEL PROVIDED WITH SAME

(71) Applicant: Sharp Kabushiki Kaisha, Osaka (JP)

(72) Inventors: Yasuhiro Kohara, Osaka (JP); Hijiri Nakahara, Osaka (JP); Junichi Morinaga, Osaka (JP)

(73) Assignee: Sharp Kabushiki Kaisha, Osaka (JP)

(21) Appl. No.: 14/401,066

(22) PCT Filed: Apr. 26, 2013
(86) PCT No.: PCT/JP2013/002854

§ 371 Date: Nov. 13, 2014

(30) Foreign Application Priority Data
May 16, 2012 (JP) 2012-112548

(51) Int. Cl. G02F 1/1362; G02F 1/1343; G02F 1/1368; G02F 1/1333; H01L 27/12; H01L 29/786

(52) U.S. Cl. CPC G02F 1/136286; H01L 27/124; H01L 27/1225; H01L 29/7869; G02F 1/1368; G02F 1/133345; G02F 1/136277; G02F 1/134309; G02F 2001/13606
USPC 349/43; 257/43

(57) ABSTRACT

This array substrate is provided with: a plurality of switching elements which are provided on a substrate; a plurality of source lines which are provided so as to extend parallel to each other and are connected to the source electrodes of the switching elements; a first interlayer insulating film which covers the source lines; a transparent electrode which is provided on the first interlayer insulating film; a second interlayer insulating film which covers the transparent electrode; and a plurality of pixel electrodes which are provided on the second interlayer insulating film so as to overlap the transparent electrode and constitute auxiliary capacitors, and which are connected to drain electrodes of the switching elements. The transparent electrode is provided with incisions at positions overlapping the source lines.

### TECHNICAL FIELD

The present invention relates to an array substrate and a liquid crystal display panel provided with the same, and in particular, relates to an array substrate provided with transparent auxiliary capacitances for respective sub-pixels and a liquid crystal display panel provided with this array substrate.

### BACKGROUND ART

An active matrix liquid crystal display panel is provided with an array substrate having switching elements such as thin film transistors (hereinafter, TFTs) or the like for each sub-pixel, which is the smallest unit of an image, an opposite substrate provided so as to face the array substrate, and a liquid crystal layer provided between the two substrates. In array substrates, an auxiliary capacitance is provided in each sub-pixel to stably maintain the liquid crystal layer, or namely, the charge supplied to the liquid crystal capacitances of the respective sub-pixels. Furthermore, in liquid crystal display panels, a single pixel is constituted of a sub-pixel for red gradient display, a sub-pixel for green gradient display, and a sub-pixel for blue gradient display, for example.

In liquid crystal display panels, there is always a demand for a greater proportion of area in each sub-pixel to be able to let light from the backlight pass through, or in other words, for a higher aperture ratio, and therefore an array substrate provided with a transparent auxiliary capacitance for each sub-pixel is gaining attention.

Patent Document 1 discloses a liquid crystal display device having a storage capacitance equivalent to the auxiliary capacitance mentioned above formed of an opposite electrode made of a transparent conductive film provided on an interlayer insulating film and on an organic insulating film stacked in this order on the TFT, an interlayer insulating film disposed so as to cover the opposite electrode, and a pixel electrode formed of a transparent conductive film provided on the interlayer insulating film, for example.

Patent Document 2 discloses a liquid crystal display device having: an auxiliary capacitance formed by a counter electrode provided in each pixel that is equivalent to each sub-pixel, the counter electrode being formed of a transparent conductive material that is in contact with a common bus line that extends between a pair of adjacent gate bus lines; a pixel electrode formed of a transparent conductive material provided in respective individual pixels; and a gate insulating film provided therebetween.

Patent Document 3 discloses a liquid crystal display panel having an auxiliary capacitance formed of an upper electrode made of a transparent conductive material that is connected to a common line that extends between a pair of adjacent scan lines through a relay terminal, a lower electrode made of a transparent conductive material connected to the drain electrode of the TFT, and an insulating film provided therebetween and respectively formed between electrodes.

### RELATED ART DOCUMENTS

### Patent Documents

Patent Document 1: Japanese Patent Application Laid-Open Publication No. 2007-328210 (FIG. 2)

Patent Document 2: Japanese Patent Application Laid-Open Publication No. 2002-14363 (FIG. 2)

Patent Document 3: Japanese Patent Application Laid-Open Publication No. 2011-53443 (FIGS. 7 and 8)

### SUMMARY OF THE INVENTION

### Problems to be Solved by the Invention

However, in the liquid crystal display device disclosed in Patent Document 2, a common bus line (with light shielding characteristics) is disposed so as to extend between the respective sub-pixels, and in the liquid crystal display panel disclosed in Patent Document 3, a common line formed of a non-transparent metal is provided so as to extend in a substantially center portion of each sub-pixel, which raises the concern of a decreased aperture ratio of each sub-pixel. Furthermore, as for the liquid crystal display device disclosed in Patent Document 1, the opposite electrode is provided between a pair of adjacent scan signal lines so as to extend widely, and the opposite electrode functions as a common bus line and a common line and thus suppresses a decrease in the aperture ratio, but there is a risk that the power consumption increases or the display quality may decrease due to the parasitic capacitance that occurs between the opposite electrode and the image signal line.

The present invention was made in view of these points, and aims at suppressing the decrease in aperture ratio caused by the auxiliary capacitance and decreasing the parasitic capacitance caused by the auxiliary capacitance.

### Means for Solving the Problems

In order to achieve the above-mentioned object, a transparent electrode that forms an auxiliary capacitance of the present invention is provided with an opening overlapping the source line.

Specifically, an array substrate according to the present invention has a substrate; a plurality of switching elements provided on the substrate, each of the plurality of switching elements having a gate electrode, a semiconductor layer, a source electrode, and a drain electrode; a plurality of source lines provided so as to extend in parallel to each other, each source line being connected to the respective source electrodes of the switching elements; a first interlayer insulating film provided so as to cover the switching elements and the source lines; a transparent electrode provided on the first interlayer insulating film; a second interlayer insulating film provided so as to cover the transparent electrode; and a plurality of pixel electrodes provided on the second interlayer insulating film so as to overlap the transparent electrode to form an auxiliary capacitance, each pixel electrode being connected to the drain electrode of the switching elements, wherein the transparent electrode has openings overlapping the source lines.

According to the configuration above, a decrease in aperture ratio due to an auxiliary capacitance can be suppressed because the auxiliary capacitance is formed of the transparent electrode covering at least one of the plurality of switching elements and at least one of the plurality of source lines, the second interlayer insulating film is provided so as to cover the transparent electrode, and the pixel electrode is connected to at least one of the drain electrodes of the plurality of switching elements, and because there is no light-shielding conductive layer provided. Furthermore, because the transparent electrode forming the auxiliary capacitance has an opening that overlaps at least one of the source lines and reduces the area in which the source line and the transparent electrode overlap, the parasitic capacitance that occurs between the source line and the transparent electrode that forms an auxiliary capacitance is reduced. Therefore, the decrease in aperture ratio caused by the auxiliary capacitance is suppressed and the parasitic capacitance caused by the auxiliary capacitance is reduced.

The array substrate may further include: a plurality of gate lines provided so as to extend in parallel to each other in a direction that intersects with the source lines, each gate line being connected to the respective gate electrodes of the switching elements, wherein among a plurality of intersections of the source lines and the gate lines, the opening is continuously formed from an outermost intersection of the plurality of intersections to another outermost intersection thereof.

According to the configuration above, because the opening of the transparent electrode is provided continuously across a plurality of portions of at least one of the source lines that intersect with the plurality of gate lines from an end portion of the plurality of portions to another end portion of the plurality of portions, most of the portion in which the source line and the transparent electrode overlap is gone, and the parasitic capacitance that occurs between the source line and the transparent electrode forming the auxiliary capacitance is reduced at an approximately optimal level.

The array substrate may further include: a plurality of gate lines provided so as to extend in parallel to each other in a direction that intersects with the source lines, each gate line being connected to the respective gate electrodes of the switching elements, wherein among a plurality of intersections of the source lines and the gate lines, the openings are formed with gaps therebetween from an outermost intersection of the plurality of intersections to another outermost intersection thereof.

According to the configuration above, because the opening of the transparent electrode is provided with gaps therebetween across a plurality of portions of at least one of the source lines that intersect with the plurality of gate lines from an end portion of the plurality of portions to another end portion of the plurality of portions, the parasitic capacitance that occurs between the source line and the transparent electrode forming the auxiliary capacitance is reduced, and the entire transparent electrode will have the same potential due to the connecting portion between the openings provided with gaps therebetween.

The source lines may have a U-shaped portion overlapping the switching elements.

According to the above-mentioned configuration, at least one of the plurality of source lines is provided in a U-shape in at least one portion overlapping the plurality of switching elements. Thus, by providing a channel of the switching element in a U-shape, even if the occupying area of the switching element is small, the channel width of the switching element is secured.

The semiconductor layer of the switching elements may be an oxide semiconductor layer.

According to the configuration above, because at least one of the semiconductor layers of the plurality of switching elements is formed of an oxide semiconductor having an electron mobility markedly higher than amorphous silicon and little variation in characteristics, the size of the switching element becomes small. As a result, in the sub-pixel, the area occupied by the switching element becomes small, and thus the aperture ratio can be improved. Furthermore, it is possible to make the frame region narrower if a switching element is provided as a circuit such as a gate driver in the frame region outside the display region, for example. Furthermore, a switching element (TFT) using an oxide semiconductor layer can operate faster than a switching element (TFT) using amorphous silicon, and thus the driving frequency increases and image display with a higher resolution can be performed. Furthermore, an oxide semiconductor film is formed with a manufacturing process simpler than a polycrystalline silicon film, and thus can be applied with ease to a manufacturing device that needs a large area.

A liquid crystal display panel according to the present invention includes: the array substrate according to any one of the array substrates mentioned above; an opposite substrate facing the array substrate; and a liquid crystal layer provided between the array substrate and the opposite substrate.

According to the configuration above, in the array substrate, the decrease in aperture ratio caused by the auxiliary capacitance is suppressed and the parasitic capacitance caused by the auxiliary capacitance is reduced, and thus specific effects of the present invention are achieved.

The opposite substrate may be provided with a common electrode.

According to the configuration above, the common electrode is provided on the opposite substrate, and thus specific effects of the present invention are achieved for vertical electrical field liquid crystal display panels such as a TN (twisted nematic) type or a VA (vertical alignment) type panel, for example.

The pixel electrodes on the array substrate may be provided in a comb shape.

According to the configuration above, at least one of the plurality of pixel electrodes is provided in a comb shape, and specific effects of the present invention are achieved in horizontal electrical field liquid crystal display panels such as an IPS (in-plane switching) type panel, for example.

### Effects of the Invention

According to the present invention, an opening is provided so that the source line overlaps the transparent electrode that forms the auxiliary capacitance, and thus a decrease in the aperture ratio caused by the auxiliary capacitance is suppressed, and the parasitic capacitance caused by the auxiliary capacitance can be reduced.

### BRIEF DESCRIPTION OF THE DRAWINGS

FIG. 1 is a cross-sectional view of the liquid crystal display device according to Embodiment 1.

FIG. 2 is a plan view that shows an array substrate included in the liquid crystal display panel according to Embodiment 1.

FIG. 3 is a cross-sectional view of the array substrate of FIG. 2 along the line III-III.

FIG. 4 is a cross-sectional view of the array substrate of FIG. 2 along the line IV-IV.

FIG. 5 is a cross-sectional view of the liquid crystal display device according to Embodiment 2.

FIG. 6 is a plan view that shows an array substrate included in the liquid crystal display panel according to Embodiment 2.

FIG. 7 is a cross-sectional view of the array substrate of FIG. 6 along the line VII-VII.

FIG. 8 is a cross-sectional view of the array substrate of FIG. 6 along the line VIII-VIII.

FIG. 9 is a plan view that shows an array substrate included in the liquid crystal display panel according to Embodiment 3.

### DETAILED DESCRIPTION OF EMBODIMENTS

Embodiments of the present invention will be described in detail below with reference to drawings. The present invention is not limited to the embodiments below.

### Embodiment 1

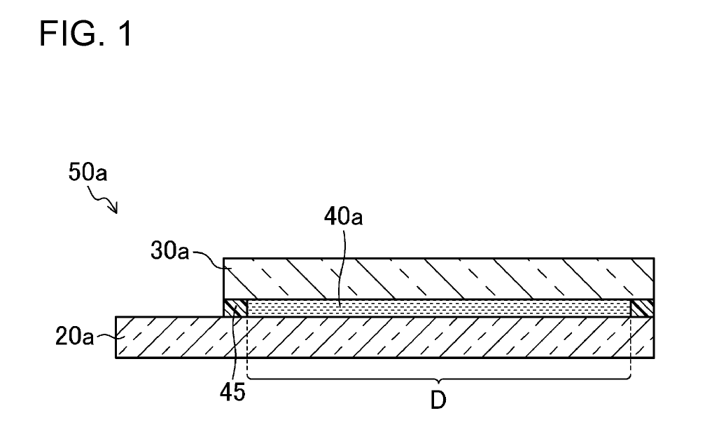

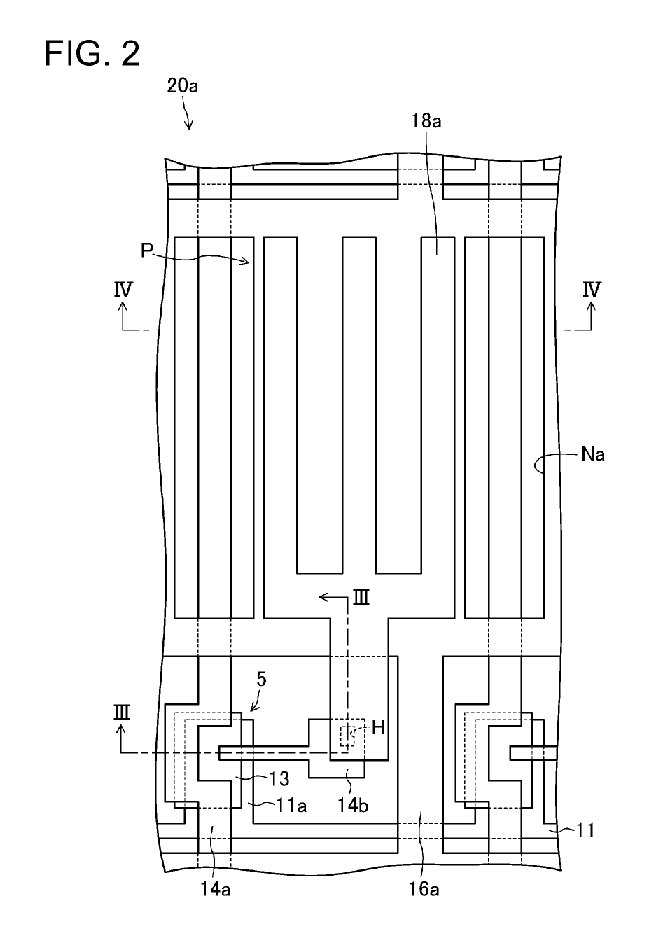

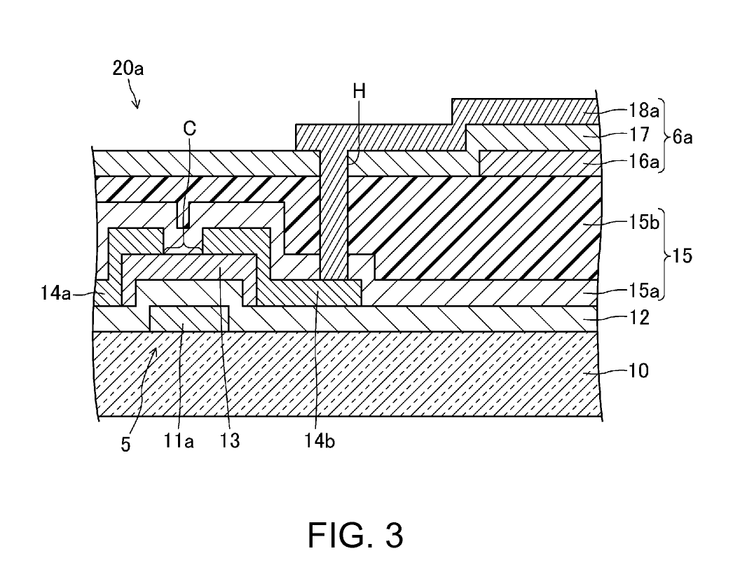

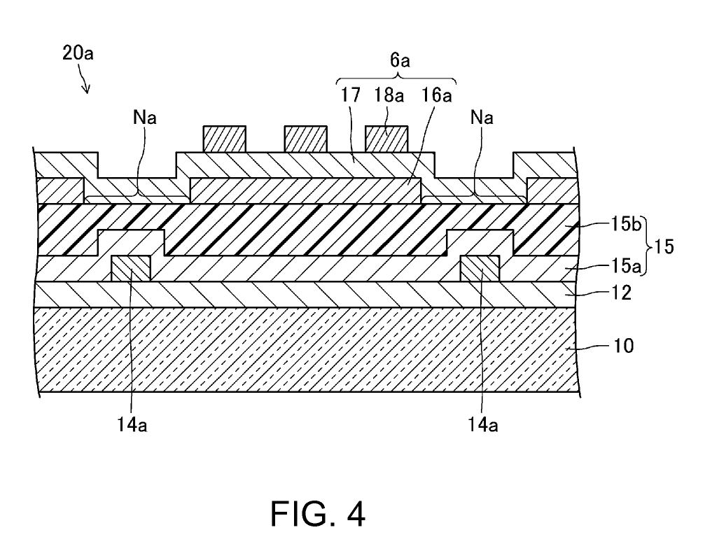

FIGS. 1 to 4 show an array substrate and a liquid crystal display panel provided therewith according to Embodiment 1 of the present invention. FIG. 1 is a cross-sectional view of a liquid crystal display panel 50a of the present embodiment. Furthermore, FIG. 2 is a plan view of an array substrate 20a included in the liquid crystal display panel 50a. FIG. 3 is a cross-sectional view of an array substrate 20a along the line III-III in FIG. 2. FIG. 4 is a cross-sectional view of an array substrate 20a along the line IV-IV in FIG. 2.

As shown in FIG. 1, the liquid crystal display panel 50a includes the array substrate 20a provided as an electrode substrate, an opposite substrate 30a provided as a non-electrode substrate so as to face the array substrate 20a, a liquid crystal layer 40a disposed between the array substrate 20a and the opposite substrate 30a, and a sealing member 45 provided in a frame shape to bond the array substrate 20a and the opposite substrate 30a so as to seal the liquid crystal layer 40a therebetween. As shown in FIG. 1, the liquid crystal display panel 50a has a display region D defined such that images are displayed in the inner side of the sealing member 45. In the display region D, a plurality of sub-pixels P (see FIG. 2), the smallest unit of an image, are disposed in a matrix. Furthermore, in the display region D, a single pixel is constituted of three RGB sub-pixels P that are provided so as to be adjacent to each other which includes a sub-pixel P for red (R) gradient display, a sub-pixel for green (G) gradient display, and a sub-pixel for blue (B) gradient display, for example.

As shown in FIGS. 2 to 4, the array substrate 20a includes a transparent substrate 10, a plurality of gate lines 11 provided on the transparent substrate 10 extending in the horizontal direction of FIG. 2 so as to be parallel to each other, a gate insulating film 12 provided so as to cover the respective gate lines 11, a plurality of source lines 14a provided so as to extend in the direction perpendicular to the respective gate lines 11 (vertical direction of FIG. 2) on the gate insulating film 12 such that the respective source lines 14a are parallel to each other, a plurality of TFTs 5 provided at each intersection of the gate lines 11 and the source lines 14a, or in other words, provided at each sub-pixel as a switching element, a first interlayer insulating film 15 provided so as to cover the respective TFTs 5 and the respective source lines 14a, a transparent electrode 16a provided on the first interlayer insulating film 15, a second interlayer insulating film 17 provided so as to cover the transparent electrode 16a, a plurality of pixel electrodes 18a provided in a matrix on the second insulating film 17 connected to the respective TFTs 5, and an alignment film (not shown) provided so as to cover each pixel electrode 18a.

As shown in FIGS. 2 and 3, the TFTs 5 are provided with a gate electrode 11a on the transparent substrate 10, the gate insulating film 12 provided so as to cover the gate electrode 11a, the semiconductor layer 13 provided in an island shape so as to be on the gate insulating film 12 and overlap the gate electrode 11a, and a source electrode (14a) and a drain electrode 14b provided on the semiconductor layer 13 so as to be separated from each other.

As shown in FIG. 2, the gate electrode 11a is a projection that projects towards a side for each sub-pixel P of the respective gate lines 11.

As shown in FIG. 2, the source electrode (14a) is a portion of the respective source lines 14a, and the source electrode (14a) has a portion that is bent in a U shape for each sub-pixel P of the respective source lines 14a.

As shown in FIGS. 2 and 3, the drain electrode 14b connects to the pixel electrode 18a through a contact hole H formed in the first interlayer insulating film 15 for each sub-pixel P.

As shown in FIG. 3, the semiconductor layer 13 has a channel region C in a portion (see FIG. 2) having a U-shape that is exposed from the source electrode (14a) and the drain electrode 14b. The semiconductor layer 13 has an intrinsic amorphous silicon layer provided on the gate insulating film 12 side, and an n+ amorphous silicon layer provided on the intrinsic amorphous silicon layer such that the channel region C of the intrinsic amorphous silicon layer is exposed, and the n+ amorphous silicon layer is respectively connected to the source electrode (14a) and the drain electrode 14b, for example. In the present embodiment, an example of a semiconductor layer 13 with an intrinsic amorphous silicon layer was shown, but the semiconductor layer 13 may be configured with polycrystalline silicon, continuous grain silicon (CGS), or oxide semiconductors such as In—Ga—Zn—O (IGZO), for example. If the semiconductor layer 13 is formed of an oxide semiconductor, then the oxide semiconductor has very high electron mobility compared to amorphous silicon, and because the variation in characteristics is small, the size of the respective TFTs 5 become smaller. As a result, the aperture ratio can be improved because the area occupied by each TFT 5 becomes smaller in the respective sub-pixels P. Furthermore, if the TFTs using oxide semiconductors are provided as circuits such as gate drivers in the frame region outside the display region D, then the frame region can be made narrower. Because TFTs using oxide semiconductors can operate faster than TFTs using amorphous silicon, the driving frequency is raised, and thus a higher resolution image display becomes possible. Furthermore, the oxide semiconductor film is formed in a simpler process than the polycrystalline silicon film, and thus can be applied with ease to manufacturing devices that needs large areas.

As shown in FIGS. 3 and 4, the first interlayer insulating film 15 is provided with an inorganic insulating film 15a provided on the gate insulating film 12 so as to cover the TFT 5, and an organic insulating film 15b provided on the inorganic insulating film 15a. In the present embodiment, an example of the first interlayer insulating film 15 having a two layer structure in which the inorganic insulating film 15a and the organic insulating film 15b are layered have been shown, but the first interlayer insulating film 15 may have a one layer structure without the organic insulating film 15b, for example.

As shown in FIGS. 1 to 4, the transparent electrode 16a is integrally formed across all of the sub-pixels P and has an opening Na provided in a rectangular shape so as to overlap the respective source lines 14a for each sub-pixel P. As shown in FIGS. 3 and 4, the transparent electrode 16a forms an auxiliary capacitance 6a by overlapping the pixel electrode 18a at each sub-pixel P with the second interlayer insulating film 17 therebetween.

As shown in FIGS. 2 and 4, the pixel electrode 18a branches and is provided such that the plurality of branch portions extend so as to be parallel to each other, and the branch portions have a comb shape (fork shape).

The opposite substrate 30a is provided with a transparent substrate, a black matrix formed in a grid pattern on the transparent substrate, a plurality of colored layers such as a red layer, a green layer, and a blue layer each provided within each of the grid cells in the black matrix, a plurality of photospacers provided in pillar shapes on the black matrix, and an alignment film provided so as to cover the respective color layers, the black matrix, and the respective photo spacers.

The liquid crystal layer 40a is made of a nematic liquid crystal material or the like having electrooptic characteristics.

The liquid crystal display panel 50a with the configuration above applies a prescribed voltage for the respective sub-pixels P to the liquid crystal layer 40a arranged between the respective pixel electrodes 18a and the transparent electrode 16a on the array substrate 20a in order to change the orientation state of the liquid crystal layer 40a with a lateral electric field, or an electric field occurring in a direction along the respective surfaces of the array substrate 20a and the opposite substrate 30a that face each other. This changes the transmittance of light passing through the panel for the respective sub-pixels P in order to display an image.

Next, a method of manufacturing the liquid crystal display panel 50a of the present embodiment will be explained. A method of manufacturing the liquid crystal display panel 50a of the present embodiment includes making an array substrate, making an opposite substrate, and injecting liquid crystal.

<Array Substrate Manufacturing Process>

First, a metal film (approximately 200 nm thick) formed of molybdenum, aluminum, titanium, tungsten, tantalum, copper, an alloy of these metals, or the like is formed on the entire substrate of the transparent substrate 10, such as a glass substrate or the like, by sputtering, for example. After the metal film is formed, photolithography, etching, stripping of the resist pattern, and then cleaning are performed on this metal film to form the gate lines 11 constituting the gate electrodes 11a.

Thereafter, an inorganic insulating film (approximately 300 nm thick) such as a silicon nitride film or a silicon oxide film, an intrinsic amorphous silicon film (approximately 100 nm thick), and an n+amorphous silicon film (approximately 50 nm thick) doped with phosphorous are sequentially deposited on the entire substrate where the gate lines 11 are formed by CVD (chemical vapor deposition), and then, photolithography, etching, stripping of the resist pattern, and cleaning are performed on the laminated film constituted of the intrinsic amorphous silicon film and n+amorphous silicon film in order to from the gate insulating film 12 and the semiconductor layer formation layer (13), for example.

After a metal film (approximately 200 nm thick) formed of molybdenum, aluminum, titanium, tungsten, tantalum, copper, an alloy of these metals, or the like are formed by sputtering, for example, on the entire substrate having the gate insulating film 12 and the semiconductor layer formation layer (13), photolithography, etching, and resist removal are conducted on the resultant metal film, thus forming the source lines 14a constituting the source electrodes (14a), and the drain electrodes 14b.

Then, by removing the n+ amorphous silicon film of the semiconductor layer formation layer (13) by etching using the source electrode (14a) and the drain electrode 14b as masks, a channel region C is formed, and the semiconductor layer 13 and the TFT 5 provided therewith are formed.

Then, the inorganic insulating film 15a is formed of a silicon nitride film, a silicon oxide film, or the like with a thickness of approximately 200 nm by the CVD method or the like. Thereafter, a resin film such as an acrylic resin is coated by spin coating or slit coating, to a thickness of approximately 2 μm onto the entire substrate having the TFTs 5, and this resin film is baked, thus forming the first interlayer insulating film 15 made of the inorganic insulating film 15a and the organic insulating film 15b, for example.

Furthermore, a transparent conductive film (approximately 50 nm thick) such as an ITO (indium tin oxide) film, an IZO (indium zinc oxide) film or the like are formed on the entire substrate where the first interlayer insulating film 15 is formed, by sputtering, and after the transparent conductive film is formed, photolithography, etching, stripping of the resist pattern, and then cleaning are performed on this transparent conductive film to form the transparent electrode 16a, for example.

Then, on the entire substrate in which the transparent electrode 16a is formed, the inorganic insulating film (approximately 300 nm thick) is formed of a silicon nitride film, a silicon oxide film, or the like by the CVD method, and then photolithography, etching, stripping of the resist pattern, and then cleaning are performed on this transparent conductive film to form the second interlayer insulating film 17 and the contact hole H in the first interlayer insulating film 15, for example.

Furthermore, a transparent conductive film (approximately 50 nm thick) such as an ITO film or an IZO film is formed on the entire substrate where the second interlayer insulating film 17 is formed by sputtering, and then the transparent conductive film is formed by photolithography, etching, stripping of the resist pattern, and then cleaning this transparent conductive film to form the pixel electrode 18a.

Finally, a polyimide resin film is coated by a printing method on the entire substrate where the pixel electrodes 18a are formed, and then this resin film undergoes a baking and rubbing treatment to form the alignment film, for example.

The array substrate 20a can be made in this manner.

In the present embodiment, an example of a method of manufacturing the semiconductor layer 13 using amorphous silicon is shown, but the semiconductor layer 13 may be formed using an In—Ga—Zn—O oxide semiconductor, for example.

<Manufacturing Opposite Substrate>

First, a black photosensitive resin is coated by spin coating or slit coating onto the entire substrate that is the transparent substrate such as a glass substrate, and then this photosensitive resin film is exposed, developed, and baked to form the black matrix at a thickness of approximately 2.0 μm, for example.

Next, a red, green, or blue photosensitive resin is coated by spin coating or slit coating onto the entire substrate where the black matrix has been formed, and then this photosensitive resin film is exposed, developed, and baked to form the colored layer of the chosen color (a red layer, for example) at a thickness of approximately 2.0 μm, for example. Then, by repeating a similar step for the other two colors, colored layers of the other two colors (green layer and blue layer, for example) are formed with a thickness of approximately 2.0 μm.

A photosensitive resin film made of a photosensitive acrylic resin or the like is coated by spin coating or slit coating, for example, on the entire substrate where the respective colored layers have been formed. Thereafter, this photosensitive resin film is exposed, developed, and baked to form photo spacers at a thickness of approximately 4.0 μm.

Finally, a polyimide resin film is coated by a printing method on the entire substrate where the photo spacers have been formed, and then this resin film undergoes a baking and rubbing treatment to form the alignment film, for example.

The opposite substrate 30a can be made in this manner.

<Injecting Liquid Crystal>

First, a sealing material made of a resin that is both UV (ultraviolet) curable and thermally curable or the like is printed in a frame shape on the surface of the opposite substrate 30a formed in the step of manufacturing the opposite substrate, for example. Thereafter, liquid crystal material is dripped into the sealing member.

Next, the opposite substrate 30a on which the liquid crystal material was dripped, and the array substrate 20a formed in the step of manufacturing the array substrate are bonded together in a depressurized state, and by subjecting the bonded body that is bonded in this manner to atmospheric pressure, the front surface and the rear surface of the bonded body are pressurized.

Furthermore, UV light is radiated on the sealing member sandwiched between this bonded member, and thereafter the sealing member is cured by heating the bonded member.

Lastly, the unnecessary portions are removed by dicing the bonded member in which the sealing member has been cured, for example.

The liquid crystal display panel 50a can be made in the manner above.

As described above, according to the array substrate 20a and the liquid crystal display panel 50a provided therewith of the present embodiment, the auxiliary capacitance 6a of the respective sub-pixels P provided in a matrix is constituted of the transparent electrode 16a disposed on the first interlayer insulating film 15 covering the respective TFTs 5 and the respective source lines 14a, the second interlayer insulating film 17 formed so as to cover the transparent electrode 16a, and the pixel electrodes 18a disposed on the second interlayer insulating film 17 and connected to the drain electrodes 14b of the respective TFTs. The auxiliary capacitance 6a does not have light-shielding characteristics, and therefore the decrease in aperture ratio caused by the auxiliary capacitance 6a can be suppressed. Furthermore, the opening Na is formed in the transparent electrode 16a constituting the auxiliary capacitance 6a so as to overlap the respective source lines 14a; thus, the area in which the respective source lines 14a and the transparent electrode 16a overlap becomes smaller, and therefore the parasitic capacitance occurring between the respective source lines 14a and the transparent electrode 16a forming the auxiliary capacitance 6a can be reduced. Therefore, the parasitic capacitance caused by the auxiliary capacitance 6a can be reduced because the decrease in aperture ratio caused by the auxiliary capacitance 6a is suppressed.

Furthermore, according to the array substrate 20a and the liquid crystal display panel 50a provided therewith of the present embodiment, the opening Na of the transparent electrode 16a is provided with gaps therebetween across one far end to another far end of the plurality of portions where the respective source lines 14a and the plurality of gate lines 11 intersect, or in other words, the opening Na is provided with gaps therebetween across a plurality of sub-pixels P disposed along the respective source lines 14a. Therefore, because of the openings Na provided with gaps therebetween, the parasitic capacitance that occurs between the respective source lines 14a and the transparent electrode 16a can be suppressed and the entire transparent electrode 16a can be reliably made the same potential by the connected portion between the openings Na provided with gaps therebetween.

Furthermore, according to the array substrate 20a and the liquid crystal display panel 50a provided therewith of the present embodiment, the respective source lines 14a are formed in a U-shape in the portion where the respective TFTs 5 are, and by providing the channel region C of the respective TFTs 5 in a U-shape, even if the area occupied by the respective TFTs 5 are small, the channel width of the respective TFTs 5 can be maintained.

Furthermore, according to the array substrate 20a and the liquid crystal display panel 50a provided therewith of the present embodiment, the parasitic capacitance caused by the auxiliary capacitance 6a can be reduced, and by decreasing the power needed to drive the respective source lines 14a, the power consumption of the entire panel can be reduced, and delay in the source signal of the respective source lines 14a can be suppressed and thus prevent a decrease in display quality.

### Embodiment 2

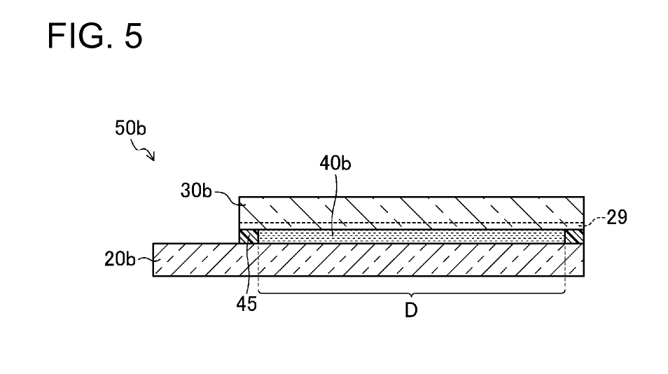

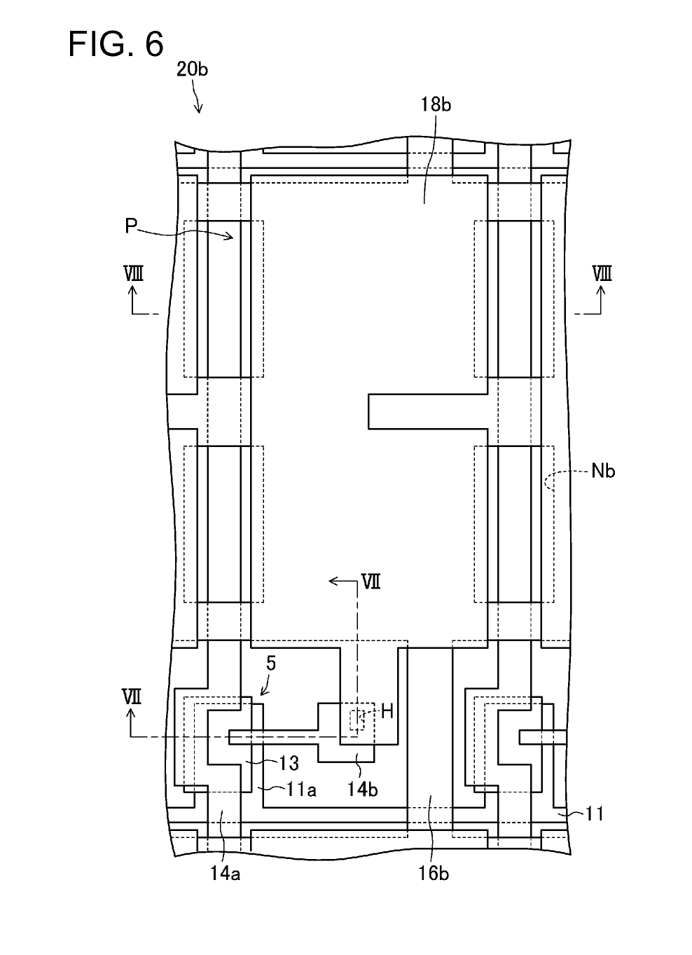

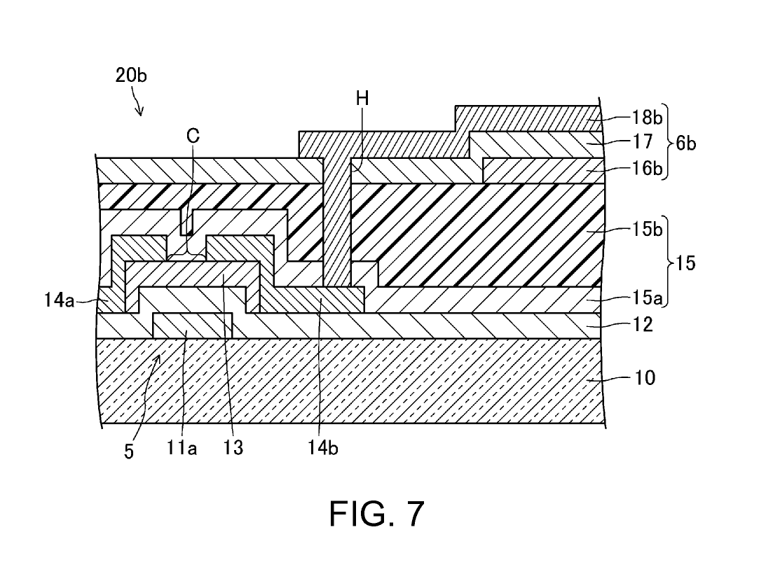

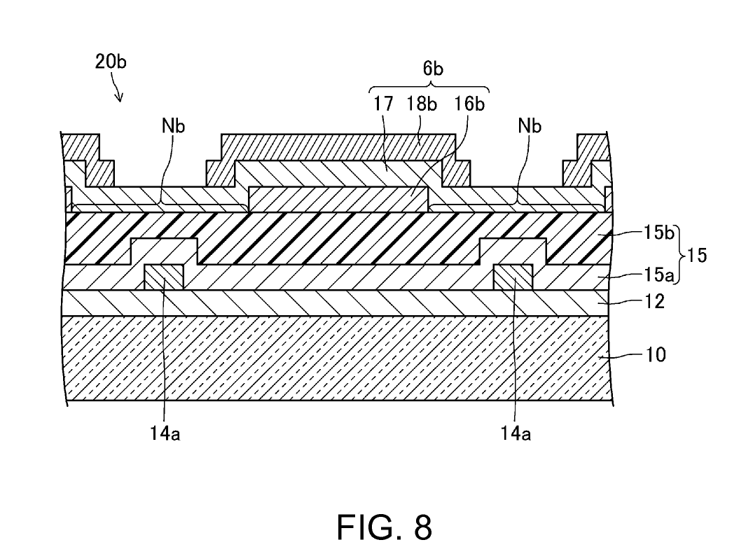

FIGS. 5 to 8 show an array substrate and a liquid crystal display panel provided therewith according to Embodiment 2 of the present invention. FIG. 5 is a cross-sectional view of a liquid crystal display panel 50b of the present embodiment. Furthermore, FIG. 6 is a plan view of an array substrate 20b included in the liquid crystal display panel 50b. Furthermore, FIG. 7 is a cross-sectional view of the array substrate 20b along the line VII-VII in FIG. 6. Furthermore, FIG. 8 is a cross-sectional view of an array substrate 20b along the line VIII-VIII in FIG. 6. In each embodiment below, the same members as those in FIGS. 1 to 4 are given the same reference characters, and the descriptions thereof are not repeated.

In Embodiment 1, a lateral electrical field liquid crystal display panel 50a was shown as an example, but in the present embodiment, a vertical electric field liquid crystal display panel 50b is shown as an example.

As shown in FIG. 5, the liquid crystal display panel 50b includes an array substrate 20b and an opposite substrate 30b that face each other, a liquid crystal layer 40b disposed between the array substrate 20b and the opposite substrate 30b, and a sealing member 45 that is provided in a frame shape that bonds the array substrate 20b and the opposite substrate 30b so as to seal the liquid crystal layer 40b therebetween.

As shown in FIGS. 6 to 8, the array substrate 20b includes: a transparent substrate 10; a plurality of gate lines 11 on the transparent substrate 10 extending parallel to each other in the horizontal direction of FIG. 6; a gate insulating film 12 covering the respective gate lines 11; a plurality of source lines 14a on the gate insulating film 12 extending parallel to each other in the direction (vertical direction in FIG. 6) that intersects the respective gate lines 11; a plurality of TFTs 5, respective TFTs being arranged on intersections of the gate lines 11 and the source lines 14a, or namely, at each of the sub-pixels P; a first interlayer insulating film 15 respectively covering the TFTs 5 and the source lines 14a; a transparent electrode 16b provided on the first interlayer insulating film 15; a second interlayer insulating film 17 covering the transparent electrode 16b; a plurality of pixel electrodes 18b connected to the respective TFTs 5 and provided in a matrix on the second interlayer insulating film 17; and an alignment film (not shown) covering the respective pixel electrodes 18b.

As shown in FIGS. 6 to 8, the transparent electrode 16b is integrally formed across all of the sub-pixels P and has a pair of openings Nb provided in a rectangular shape so as to overlap the respective source lines 14a for each sub-pixel P. As shown in FIGS. 7 and 8, the transparent electrode 16b forms an auxiliary capacitance 6b by overlapping the pixel electrode 18b at each sub-pixel P with the second interlayer insulating film 17 therebetween.

The opposite substrate 30b is provided with a transparent substrate, a black matrix formed in a grid pattern on the transparent substrate, a plurality of colored layers such as a red layer, a green layer, and a blue layer each provided within each of the grid cells in the black matrix, a common electrode 29 (see FIG. 5) provided so as to cover the black matrix and the respective colored layers, a plurality of photospacers provided in pillar shapes on the common electrode 29, and an alignment film provided so as to cover the common electrode 29 and the respective photo spacers.

The liquid crystal layer 40b is made of a nematic liquid crystal material or the like that has electrooptic characteristics. When using vertical alignment mode devices, the above-mentioned liquid crystal material has liquid crystal molecules having a negative dielectric anisotropy, and when using horizontal alignment mode devices, the liquid crystal material includes liquid crystal molecules having a positive dielectric anisotropy.

The liquid crystal display panel 50b with the above-mentioned configuration has a prescribed voltage applied to each sub-pixel P of the liquid crystal layer 40b disposed between the respective pixel electrodes 18b on the array substrate 20b and the common electrode 29 on the opposite substrate 30b in order to change the orientation state of the liquid crystal layer 40b with a vertical electric field, or an electric field occurring in a direction along the thickness direction of the array substrate 20b and the opposite substrate 30b. This changes the transmittance of light passing through the panel for the respective sub-pixels P in order to display an image.

In the liquid crystal display panel 50b of the present embodiment, during the manufacturing process of the array substrate in Embodiment 1 mentioned above, the array substrate 20b is manufactured by changing the pattern for etching the transparent conductive film to form the transparent electrode 16a, and changing the pattern of etching the transparent conductive film for forming the pixel electrode 18a. During the manufacturing process of the opposite substrate, the opposite substrate 30b is manufactured between the steps of forming the respective colored layers and the steps of forming the photospacer by the transparent conductive film (approximately 50 nm thick) such as an ITO film, an IZO film, or the like being formed by sputtering, and by adding a step to form the common electrode 29. In a similar manner to Embodiment 1, the liquid crystal display panel 50b can be manufactured by the process of injecting liquid crystal.

As described above, according to the array substrate 20b and the liquid crystal display panel 50b provided therewith, in a similar manner to Embodiment 1 mentioned above, the opening Nb is formed in the transparent electrode 16b that is included in the auxiliary capacitance 6b, so as to overlap the respective source lines 14a, therefore the decrease in the aperture ratio caused by the auxiliary capacitance 6b is suppressed, and thus the parasitic capacitance caused by the auxiliary capacitance 6b can be reduced.

### Embodiment 3

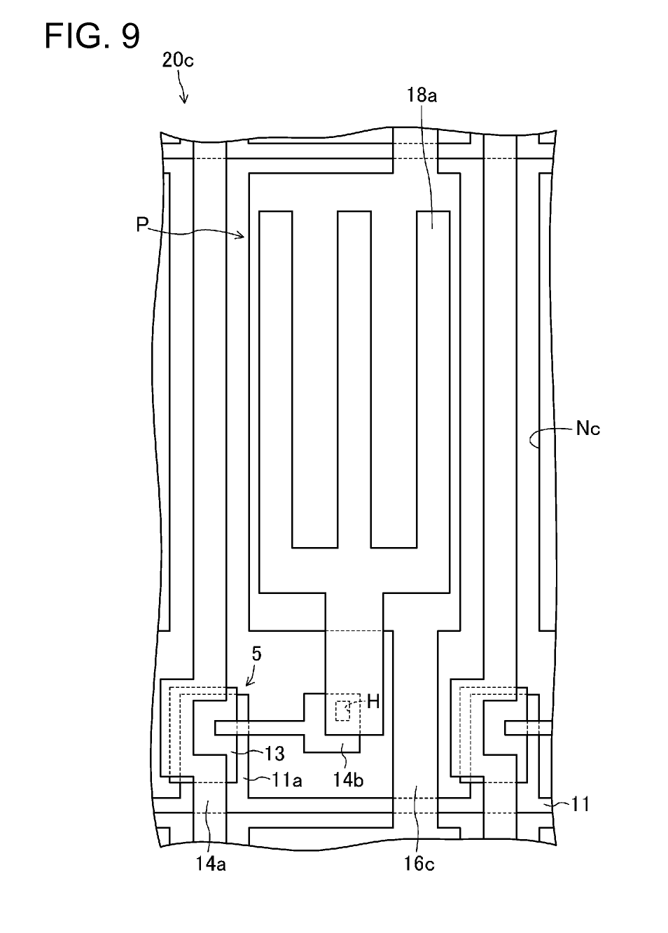

FIG. 9 is a plan view of an array substrate 20c included in a liquid crystal display panel of the present embodiment.

In the above-mentioned Embodiments 1 and 2, examples of liquid crystal display panels 50a and 50b provided with array substrates having openings in a transparent electrode disposed with gaps therebetween across a plurality of sub-pixels P along respective source lines 14a was shown, but in the present embodiment, an example of a liquid crystal display panel provided with an array substrate 20c having openings in a transparent electrode disposed with gaps therebetween across a plurality of sub-pixels P along respective source lines 14a is shown.

The liquid crystal display panel of the present embodiment includes the array substrate 20c (see FIG. 9) provided as an electrode substrate, an opposite substrate 30a (see FIG. 1) provided as a non-electrode substrate so as to face the array substrate 20c, a liquid crystal layer 40a (see FIG. 1) disposed between the array substrate 20c and the opposite substrate 30a, and a sealing member 45 (see FIG. 1) provided in a frame shape to bond the array substrate 20c to the opposite substrate 30a so as to seal the liquid crystal layer 40a therebetween.

As shown in FIG. 9, the array substrate 20c includes: a transparent substrate 10 (see FIG. 3); a plurality of gate lines 11 on the transparent substrate 10 extending parallel to each other in the horizontal direction of FIG. 9; a gate insulating film 12 covering the respective gate lines 11; a plurality of source lines 14a on the gate insulating film 12 extending parallel to each other in the direction (vertical direction in FIG. 9) that intersects the respective gate lines 11; a plurality of TFTs 5 being arranged on respective intersections of the gate lines 11 and the source lines 14a, or namely, on each of the sub-pixels P as switching elements; a first interlayer insulating film 15 (see FIG. 3) covering the respective TFTs 5 and the respective source lines 14a; a transparent electrode 16c provided on the first interlayer insulating film 15; a second interlayer insulating film 17 (see FIG. 3) covering the transparent electrode 16c; a plurality of pixel electrodes 18a connected to the respective TFTs 5 and provided in a matrix on the second interlayer insulating film 17; and an alignment film (not shown) covering the respective pixel electrodes 18a.

As shown in FIG. 9, the transparent electrode 16c is integrally formed in a comb shape across all sub-pixels P, and has an opening Nc that is formed so as to continuously overlap respective source lines 14a across the sub-pixel P that coincides with the respective source lines 14a. Furthermore, the transparent electrode 16c includes auxiliary capacitances in the respective sub-pixels P by overlapping the pixel electrodes 18a with the second interlayer insulating film 17 therebetween. In FIG. 9, the transparent electrode 16c disposed on each sub-pixel P is shown such that the transparent electrode 16c has independent portions, but this transparent electrode 16c is connected outside of the display region D.

The liquid crystal display panel of the present embodiment applies a prescribed voltage for the respective sub-pixels P to the liquid crystal layer 40a arranged between the respective pixel electrodes 18a on the array substrate 20a and the transparent electrode 16a in order to change the orientation state of the liquid crystal layer 40a with a lateral electric field, or an electric field occurring in a direction along the respective surfaces of the array substrate 20c and the opposite substrate 30a that face each other. This changes the transmittance of light passing through the panel for the respective sub-pixels P in order to display an image.

Furthermore, the liquid crystal display panel of the present embodiment can be manufactured by manufacturing the array substrate 20c through changing the pattern for etching the transparent conductive film to form the transparent electrode 16a and by performing the opposite substrate manufacturing step and the liquid crystals injecting step in a manner similar to Embodiment 1.

As described above, according to the array substrate 20c and the liquid crystal display panel provided therewith of the present embodiment, in a similar manner to Embodiments 1 and 2, an opening Nc is provided so that the source line 14a overlaps the transparent electrode 16c that forms the auxiliary capacitance, and thus a decrease in the aperture ratio caused by the auxiliary capacitance is suppressed, and the parasitic capacitance caused by the auxiliary capacitance can be reduced.

Furthermore, according to the array substrate 20c and the liquid crystal display panel provided therewith of the present embodiment, the opening Nc of the transparent electrode 16c is provided continuously across one far end to another far end of the plurality of portions where the respective source lines 14a and the plurality of gate lines 11 intersect, or in other words, the openings Na are provided continuously across a plurality of sub-pixels P disposed along the respective source lines 14a. Therefore, because the portion where the respective source lines 14a and the transparent electrode 16c that forms the auxiliary capacitance overlap is almost gone, the parasitic capacitance that occurs between the respective source lines 14a and the transparent electrode 16c forming the auxiliary capacitance can be reduced at a near optimal level.

In Embodiment 1, a configuration in which the lateral electrical field liquid crystal display panel 50a provided with the transparent electrode 16c having the opening Nc was shown, but in the present embodiment, a configuration in which the vertical electrical field liquid crystal display panel 50a provided in Embodiment 2 including the transparent electrode 16c having the opening Nc can be used.

Furthermore, in the respective embodiments above, an array substrate having the TFT switching elements for each of the respective sub-pixels P and the liquid crystal display panel provided therewith are shown as examples, but the present invention can also be applied to an array substrate having other three terminal switching elements such as MOS-FET switching elements for the respective sub-pixels P and a liquid crystal display panel provided therewith.

Furthermore, in the respective Embodiments above, an array substrate having bottom gate TFTs for respective sub-pixels P and a liquid crystal display panel provided therewith are shown as examples, but the present invention can be applied to an array substrate having top gate TFTs for respective sub-pixels P and a liquid crystal display panel provided therewith.

Furthermore, in the respective embodiments above, an array substrate having a plurality of sub-pixels P arranged in a matrix and a liquid crystal display panel provided therewith are shown as examples, but the present invention can adopt an array substrate having a plurality of sub-pixels P arranged in a delta pattern and a liquid crystal display panel provided therewith.

Furthermore, in the respective embodiments above, a liquid crystal display panel provided with a transparent auxiliary capacitance for each sub-pixel P is shown as an example, but in the present invention, other display panels such as an organic EL (electroluminescence) panel can be adopted.

In the respective embodiments above, examples were shown of a TFT substrate in which the electrode of the TFT connected to the pixel electrode was the drain electrode, but the present invention can be applied to a TFT substrate in which the electrode of the TFT connected to the pixel electrode is the source electrode.

### INDUSTRIAL APPLICABILITY

As described above, because the decrease in aperture ratio caused by the auxiliary capacitance can be suppressed and the parasitic capacitance caused by the auxiliary capacitance can be reduced, the present invention is useful for a liquid crystal display panel and an array substrate included therein.

### DESCRIPTION OF REFERENCE CHARACTERS

Na to Nc opening
5 TFT (switching element)
6a, 6b auxiliary capacitance
gate line
11a gate electrode
13a semiconductor layer
14a source line, source electrode
14b drain electrode
15 first interlayer insulating film
16a to 16e transparent electrode
18a, 18b pixel electrode
20a to 20c array substrate
29 common electrode
30a, 30b opposite substrate
40 liquid crystal layer
50a, 50b liquid crystal display panel

1. An array substrate, comprising:
a substrate;
a plurality of switching elements provided on the substrate, each of the plurality of switching elements having a gate electrode, a semiconductor layer, a source electrode, and a drain electrode;
a plurality of source lines provided so as to extend in parallel to each other, each source line being connected to the respective source electrodes of the switching elements adjacent thereto;
a first interlayer insulating film covering substantially an entirety of an area where the switching elements and the source lines are provided;
a transparent electrode provided on the first interlayer insulating film;
a second interlayer insulating film provided so as to cover the transparent electrode; and
a plurality of pixel electrodes provided on the second interlayer insulating film so as to overlap the transparent electrode to form an auxiliary capacitance, each pixel electrode being connected to the drain electrode of the switching elements adjacent to the pixel electrode,
wherein the transparent electrode has openings overlapping at least portions of the source lines.

2. The array substrate according to claim 1, further comprising:
a plurality of gate lines provided so as to extend in parallel to each other in a direction that intersects with the source lines, each gate line being connected to the respective gate electrodes of the switching elements adjacent to the gate line,
wherein each of the openings covers one of the source lines in its entirety.

3. The array substrate according to claim 1, further comprising:
a plurality of gate lines provided so as to extend in parallel to each other in a direction that intersects with the source lines, each gate line being connected to the respective gate electrodes of the switching elements adjacent to the gate line,
wherein each of the openings covers one of the source lines such that the openings cover only portions of the source line.

4. The array substrate according to claim 1, wherein the source lines have a U-shaped portion overlapping the switching elements.

5. The array substrate according to claim 1, wherein the semiconductor layer of the switching elements is an oxide semiconductor layer.

6. A liquid crystal display panel, comprising:
the array substrate according to claim 1;
an opposite substrate facing the array substrate; and
a liquid crystal layer provided between the array substrate and the opposite substrate.

7. The liquid crystal display panel according to claim 6, wherein the opposite substrate is provided with a common electrode.

8. The liquid crystal display panel according to claim 6, wherein the pixel electrodes on said array substrate are provided in a comb shape.

9. The array substrate according to claim 2, wherein the source lines have a U-shaped portion overlapping the switching elements.

10. The array substrate according to claim 3, wherein the source lines have a U-shaped portion overlapping the switching elements.

11. The array substrate according to claim 2, wherein the semiconductor layer of the switching elements is an oxide semiconductor layer.

12. The array substrate according to claim 3, wherein the semiconductor layer of the switching elements is an oxide semiconductor layer.

13. The array substrate according to claim 4, wherein the semiconductor layer of the switching elements is an oxide semiconductor layer.

14. The array substrate according to claim 9, wherein the semiconductor layer of the switching elements is an oxide semiconductor layer.

15. The array substrate according to claim 10, wherein the semiconductor layer of the switching elements is an oxide semiconductor layer.

16. The array substrate according to claim 5, wherein the semiconductor layer is an In—Ga—Zn—O semiconductor layer.

17. The array substrate according to claim 11, wherein the semiconductor layer is an In—Ga—Zn—O semiconductor layer.

18. The array substrate according to claim 12, wherein the semiconductor layer is an In—Ga—Zn—O semiconductor layer.

19. The array substrate according to claim 13, wherein the semiconductor layer is an In—Ga—Zn—O semiconductor layer.

20. The array substrate according to claim 14, wherein the semiconductor layer is an In—Ga—Zn—O semiconductor layer.
